(19) United States
(12) Patent Application Publication
(10) Pub. No.: US 2025/0107255 A1
(43) Pub. Date: Mar. 27, 2025

(54) IMAGE SENSOR

(71) Applicant: SAMSUNG ELECTRONICS CO., LTD., Suwon-si (KR)

(72) Inventors: Kyungduck LEE, Suwon-si (KR); Taesub JUNG, Suwon-si (KR); Masato FUJITA, Suwon-si (KR); Yunha NA, Suwon-si (KR); Seungki BAEK, Suwon-si (KR); Doosik SEOL, Suwon-si (KR); Sungmin AN, Suwon-si (KR); Seungki JUNG, Suwon-si (KR)

(73) Assignee: SAMSUNG ELECTRONICS CO., LTD., Suwon-si (KR)

(21) Appl. No.: 18/654,727

(22) Filed: May 3, 2024

(30) Foreign Application Priority Data
Sep. 26, 2023 (KR) 10-2023-0129568

(51) Int. Cl. H01L 27/146

(52) U.S. Cl. CPC H10F 39/8023; H10F 39/80373; H10F 39/807

(57) ABSTRACT

An image sensor includes pixels, each including two photodiodes arranged side-by-side in a first direction, a deep trench isolation structure, a floating diffusion region, and transfer gates. The deep trench isolation structure includes an inner structure that extends in a second direction perpendicular to the first direction and that separates the two PDs of pixel from each other in the first direction, and an outer structure that extends in the first and second directions and that separates the pixels from each other in the first and second directions. The floating diffusion region is arranged between a center portion of the outer structure extending in the first direction and an edge of the inner structure. The transfer gates are disposed adjacent to the floating diffusion region such that one or more transfer gates are disposed on each photodiode. For each pixel, the two photodiodes share the floating diffusion region.

### CROSS-REFERENCE TO RELATED APPLICATION

This application is based on and claims priority under 35 U.S.C. § 119 to Korean Patent Application No. 10-2023-0129568, filed on Sep. 26, 2023, in the Korean Intellectual Property Office, the disclosure of which being incorporated by reference herein in its entirety.

### BACKGROUND

Apparatuses and devices consistent with the present disclosure relate to an image sensor, and more particularly, to an image sensor including a two-photodiode (2PD) pixel structure.

Image sensors typically have a plurality of unit pixels arranged in a two-dimensional array structure. Recently, the size of pixels has been reduced, a share-pixel structure has been proposed. However, the share-pixel structure increases complexity in arrangement and causes a disadvantage in that the conversion gain and arrangement efficiency of the image sensor may be decreased.

### SUMMARY

It is an aspect to provide an image sensor configured to improve a conversion gain (CG), increase the arrangement efficiency and the size of pixel transistors, and reduce metal wiring layers.

According to an aspect of one or more embodiments, there is provided an image sensor comprising a plurality of pixels, each comprising two photodiodes (PDs) arranged side-by-side in a first direction; a deep trench isolation (DTI) structure comprising an inner DTI structure that extends in a second direction perpendicular to the first direction and that separates the two PDs of each of the plurality of pixels from each other in the first direction, and an outer DTI structure that extends in the first direction and the second direction and that separates the plurality of pixels from each other in the first direction and the second direction; a floating diffusion (FD) region arranged between a center portion of the outer DTI structure extending in the first direction and an edge of the inner DTI structure; and a plurality of transfer gates (TGs) disposed adjacent to the FD region such that at least one TG of the plurality of TGs is disposed on each PD, wherein, for each of the plurality of pixels, the two PDs of the pixel share the FD region.

According to another aspect of one or more embodiments, there is provided an image sensor comprising a share-pixel comprising four pixels, each of the four pixels comprising two photodiodes (PDs) arranged side-by-side in a first direction; a deep trench isolation (DTI) structure comprising an inner DTI structure that extends in a second direction perpendicular to the first direction and separates the two PDs of each of the four pixels from each other in the first direction, and an outer DTI structure that extends in the first direction and the second direction and separates the four pixels from each other in the first direction and the second direction; a floating diffusion (FD) region disposed between a center portion of the outer DTI structure extending in the first direction and an edge of the inner DTI structure; a plurality of transfer gates (TGs) arranged adjacent to the FD region such that at least one TG of the plurality of TGs is disposed on each PD; a reset gate (RG) disposed in any one of the four pixels of the share-pixel at an inner portion of the share-pixel; and a source follower gate (SF) disposed in at least one other pixel of the four pixels of the share-pixel and adjacent to the RG at the inner portion of the share-pixel, wherein the two PDs of each of the pixels share the FD region.

According to yet another aspect of one or more embodiments, there is provided an image sensor comprising a share-pixel comprising four pixels, each of the four pixels comprising two photodiodes (PDs) arranged side-by-side in a first direction; a deep trench isolation (DTI) structure comprising an inner DTI structure that extends in a second direction perpendicular to the first direction and separates the two PDs of each of the four pixels from each other in the first direction, and an outer DTI structure that extends in the first direction and the second direction and separates the four pixels from each other in the first direction and the second direction; a floating diffusion (FD) region disposed between a center portion of the outer DTI structure extending in the first direction and an edge of the inner DTI structure; and a plurality of transfer gates (TGs) arranged adjacent to the FD region such that at least one TG of the plurality of TGs is disposed on each PD, wherein each group of two pixels that are adjacent to each other in the second direction, of the four pixels, forms a sub-share-pixel, the share-pixel comprises two sub-share-pixels adjacent to each other in the first direction, the FD region is disposed between the two pixels of each of the sub-share-pixels, and the four PDs of each of the sub-share-pixels share the FD region of the sub-share-pixel.

### BRIEF DESCRIPTION OF THE DRAWINGS

Various embodiments will be more clearly understood from the following detailed description taken in conjunction with the accompanying drawings, in which:

FIG. 1 is an equivalent circuit diagram corresponding to a share-pixel of an image sensor according to an embodiment;

FIG. 2 is a plan view illustrating the share-pixel of the image sensor shown in FIG. 1, according to an embodiment;

FIGS. 3A and 3B are plan views respectively illustrating a floating diffusion (FD)-region wiring routing of an image sensor of a comparative example and an FD-region wiring routing of the image sensor shown in FIG. 1;

FIGS. 4A and 4B are plan views illustrating share-pixels of image sensors according to some embodiments;

FIGS. 5A to 5C are respectively a plan view illustrating a share-pixel of an image sensor and cross-sectional views illustrating transfer gates of image sensors according to some embodiments;

FIGS. 6A and 6B are plan views respectively illustrating a share-pixel of an image sensor and an FD-region wiring routine of the image sensor according to some embodiments;

FIGS. 7 to 11 are plan views illustrating share-pixels of image sensors according to some embodiments;

FIG. 12 is a plan view illustrating a structure in which share-pixels of the image sensor shown in FIG. 2 are arranged in a two-dimensional array structure, according to an embodiment;

FIG. 13 is a block diagram illustrating an image sensor according to an embodiment; and

FIG. 14 is a block diagram illustrating an electronic device including an image sensor according to an embodiment.

### DETAILED DESCRIPTION

Aspects of the embodiments of the present disclosure are not limited to those mentioned above, and other aspects of the various embodiments will be apparently understood by those skilled in the art through the following description.

In general, each unit pixel may include a photodiode and a plurality of pixel transistors. For example, the pixel transistors may include a transfer transistor, a reset transistor, a source follower transistor, and a selection transistor. Recently, the size of pixels has reduced, and thus, image sensors employ a share-pixel structure in which a plurality of pixels share pixel transistors to relatively increase the area of photodiodes. In the share-pixel structure, pixels may be separated from each other by a deep trench isolation (DTI) structure

Hereinafter, various embodiments will be described with reference to the attached drawings. In the drawings, like reference numerals denote like elements, and repeated descriptions thereof are omitted for conciseness.

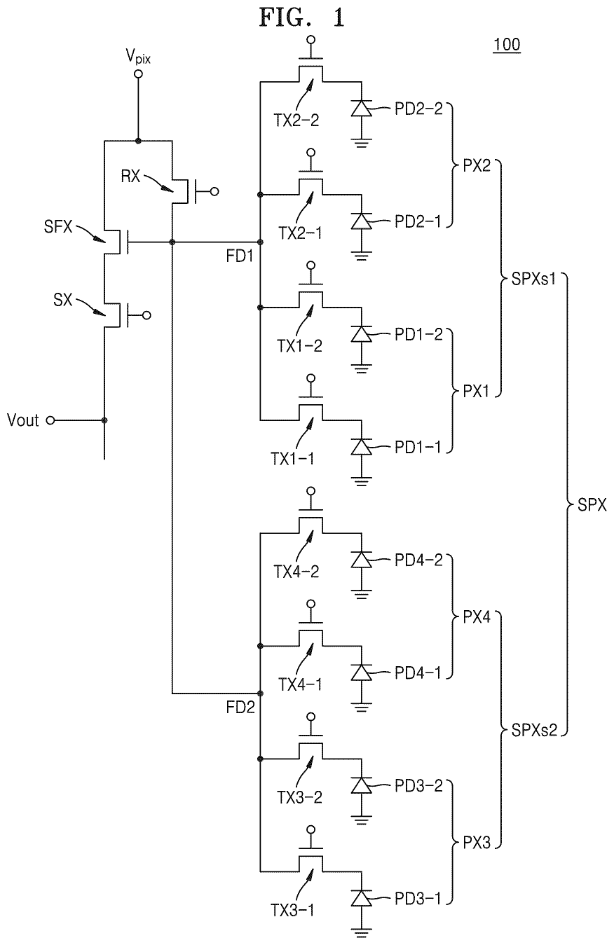

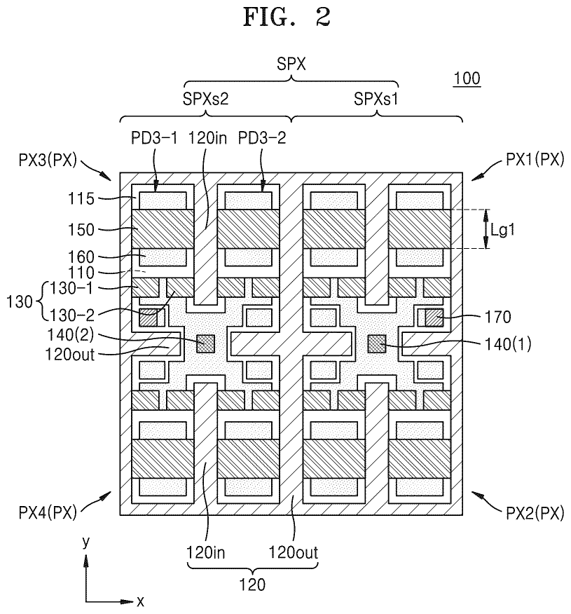

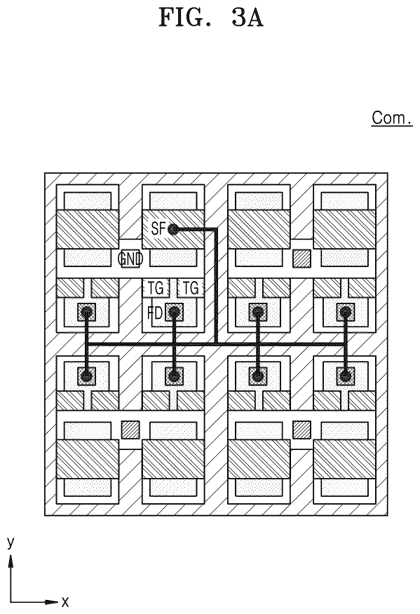

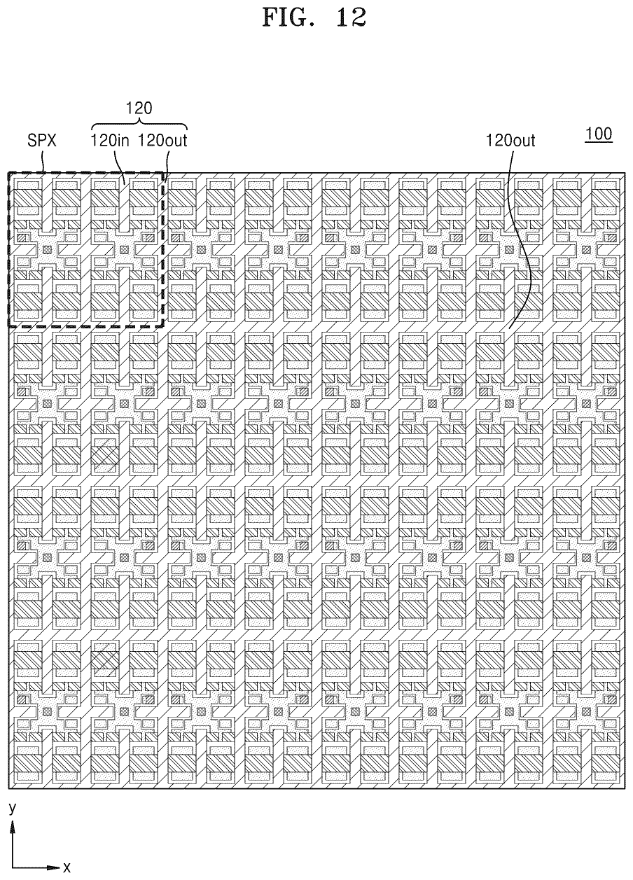

FIG. 1 is an equivalent circuit diagram corresponding to a share-pixel SPX of an image sensor 100 according to an embodiment, and FIG. 2 is a plan view illustrating the share-pixel SPX of the image sensor 100 shown in FIG. 1, according to an embodiment. The image sensor 100 may include a plurality of share-pixels SPX arranged in a two-dimensional array structure on a substrate. (see, e.g., FIG. 12).

Referring to FIGS. 1 and 2, a spare-pixel SPX of the plurality of share-pixels SPX is illustrated by way of example. Each of the share-pixels SPX may include four unit pixels PX arranged in a 2*2 structure. For example, the four unit pixels PX may include a first unit pixel PX1, a second unit pixel PX2, a third unit pixel PX3, and a fourth unit pixel PX4. Hereinafter, the term “unit pixel” is simply referred to as “pixel” for convenience of description.

Each of the first to fourth pixels PX1 to PX4 may include two photodiodes (PDs) 110. For example, the first pixel PX1 may include a first PD PD1-1 and a second PD PD1-2, the second pixel PX2 may include a third PD PD2-1 and a fourth PD PD2-2, the third pixel PX3 may include a fifth PD PD3-1 and a sixth PD PD3-2, and the fourth pixel PX4 may include a seventh PD PD4-1 and an eighth PDPD4-2.

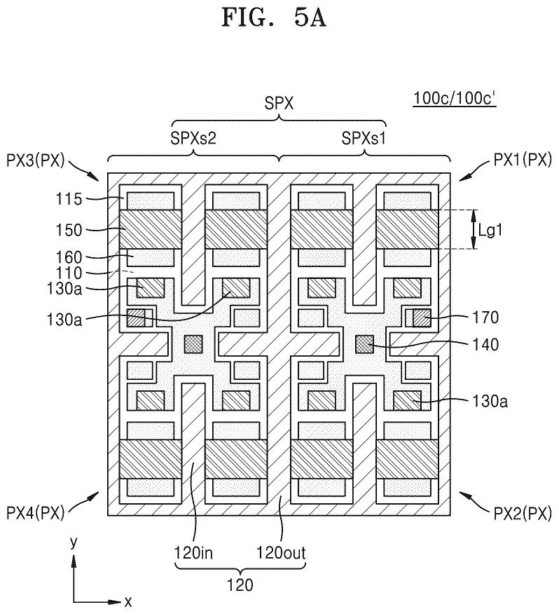

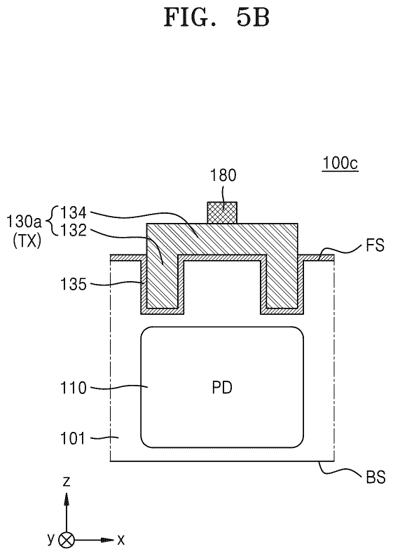

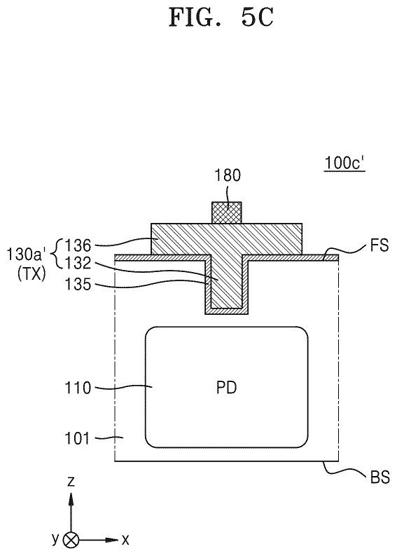

Each of the four pixels PX may include the two PDs 110, a portion of a floating diffusion (FD) region 140, and at least one pixel transistor. In a vertical structure, the pixel transistors may be disposed on a surface portion of the substrate (for example, refer to a substrate 101 shown in FIG. 5C), and the PDs 110 may be disposed in the substrate 101. For example, the PDs 110 may be disposed in lower portions of active regions 160 of the pixel transistors. Therefore, in FIG. 2, portions exposed between a deep trench isolation (DTI) structure 120 and the active regions 160 may correspond to device isolation layers 115, and the PDs 110 may not be exposed to the outside of the DTI structure 120. In some embodiments, the pixel transistors may include, for example, a transfer transistor TX, a reset transistor RX, a source follower transistor SFX, and/or a selection transistor SX. The substrate 101 and the PDs 110 are further described with reference to FIGS. 5A to 5C.

In some embodiments, the device isolation layers 115 may be disposed on a front side FS (refer to FIG. 5B) of the substrate 101 and may define the active regions 160. In some embodiments, each of the active regions 160 may include a region in which a transfer gate 130 and an FD region 140 are provided, a region in which a gate 150 is provided, and a region in which a ground contact 170 is provided. Bottom surfaces of the device isolation layers 115 may be spaced apart from the PDs 110. The depth of the device isolation layers 115 may be less than the depth of the DTI structure 120. The device isolation layers 115 may be, for example, shallow trench isolation (STI) layers. The DTI structure 120 may overlap portions of the device isolation layers 115. For example, the DTI structure 120 may extend through the device isolation layers 115.

Each of the pixels PX may include two PDs 110, and two transfer gates 130 may be arranged on each of the PDs 110. For example, each of the first and second PDs PD1-1 and PD1-2 of the first pixel PX1 may include a first transfer gate 130-1 and a second transfer gate 130-2. The first transfer gate 130-1 and the second transfer gate 130-2 may transfer charge generated by a corresponding PD 110 to an adjacent FD region 140. Leakage of charges may be reduced by disposing the two transfer gates 130 on one PD 110. In some embodiments, one PD 110, two transfer gates 130, and an FD region 140 may form one transfer transistor TX. In some embodiments, each of the two transfer gates 130 may have a single vertical gate structure similar to that shown in FIG. 5C. However, the structure of the transfer gates 130 is not limited to the single vertical gate structure.

Four pixels PX may be separated from each other by the DTI structure 120. In some embodiments, the two PDs 110 in each of the four pixels PX may also be separated from each other by the DTI structure 120, as illustrated in FIG. 2. For example, the DTI structure 120 may include an outer DTI structure 120out that separates the pixels PX from each other, and an inner DTI structure 120 in that separates the two PDs 110 in each of the pixels PX from each other.

The outer DTI structure 120out may include a portion extending in an x-direction and a portion extending in a y-direction. The portion of the outer DTI structure 120out extending in the y-direction may completely separate two adjacent pixels PX from each other in the x-direction. The portion of the outer DTI structure 120out extending in the x-direction may partially separate two adjacent pixels PX from each other in the y-direction. For example, the portion of the outer DTI structure 120out extending in the x-direction may be divided into two parts by a portion of an FD region 140.

The inner DTI structure 120 in may be disposed in each of the pixels PX and extend in the y-direction to separate two PDs 110 from each other. Therefore, in each of the pixels PX, the two PDs 110 may be disposed on respective sides of the inner DTI structure 120 in in the x-direction. In some embodiments, two transfer gates 130 may be disposed on each side of the inner DTI structure 120 in in the x-direction. In other words, for example with reference to the third pixel PX3 in FIG. 2, the first transfer gate 130-1 and the second transfer gate 130-2 of the fifth PD PD3-1 may be disposed on one side of the inner DTI structure 120 in separating the fifth PD PD3-1 from the sixth PD PD3-2, and the first transfer gate 130-1 and the second gate 130-2 of the sixth PD PD3-2 may be disposed on the other side of the inner DTI structure 120 in separating the fifth PD PD3-1 from the sixth PD PD3-2. The FD region 140 may be adjacent to an edge of the inner DTI structure 120 in in the y-direction.

In some embodiments, the x-direction and the y-direction are relative concepts. When the share-pixel SPX is rotated by 90°, the x-direction may be the y-direction and the y-direction may be the x-direction. Therefore, the extension directions and structures of the outer DTI structure 120out and the inner DTI structure 120 in may not be limited to the directions and structures described above.

In some embodiments, the DTI structure 120 may prevent charges generated by light incident on the PDs 110 of a specific pixel PX from entering adjacent pixels PX or PDs 110. That is, the DTI structure 120 may prevent optical crosstalk between adjacent pixels PX. The DTI structure 120 may extend from the front side FS to a back side BS (refer to FIG. 5C) of the substrate 101 and may penetrate the substrate 101.

The DTI structure 120 will now be further described. The DTI structure 120 may include a center conductive layer and an outer insulating layer. The center conductive layer may be disposed in a center portion of the DTI structure 120 and may include, for example, polysilicon doped with a dopant. A ground or negative voltage may be applied to the center conductive layer. When the ground or negative voltage is applied to the center conductive layer, positive charges generated by the pixels PX may be induced by the voltage of the center conductive layer and removed through a ground contact. As a result, the DTI structure 120 may improve dark current characteristics of the image sensor 100 through the center conductive layer. The outer insulating layer may be disposed on an outer portion of the DTI structure 120 to surround the center conductive layer. The outer insulating layer may insulate the center conductive layer from the substrate 101. The outer insulating layer may include, for example, a silicon oxide layer, a silicon oxynitride layer, or a silicon nitride layer.

In some embodiments, a buried layer may be disposed in the center conductive layer. The buried layer may have functions such as preventing the formation of voids in the DTI structure 120, and preventing bending of the substrate 101 by offsetting tensile stress applied to the substrate 101 during a high temperature process. Therefore, the buried layer may include a material having a thermal expansion coefficient that is different from that of the center conductive layer. For example, the buried layer may include a metal oxide, a metal nitride, a metal, or a combination thereof. Alternatively, the buried layer may include a silicon compound such as SiCN, SiON, SiOC, or the like.

The DTI structure 120 may be provided by forming a deep trench in the substrate 101 and filling the inside of the deep trench with an insulating material and a conductive material. The DTI structure 120 may be referred to as a front DTI (FDTI) structure or a back DTI (BDTI) structure depending on whether the deep trench is formed in the front side FS or the back side BS of the substrate 101. In some embodiments, the DTI structure 120 may have various shapes depending on the shape of the trench. For example, in some embodiments, the DTI structure 120 may not completely penetrate the substrate 101. In the image sensor 100 of the embodiment illustrated in FIGS. 1 and 2, the DTI structure 120 may have an FDTI structure. However, the DTI structure 120 is not limited thereto.

The FD region 140 may be placed between two adjacent pixels PX in the y-direction. For example, the FD region 140 may be formed through high-concentration dopant doping in an active region 160 between two adjacent pixels PX in the y-direction. For example, a first FD region 140(1) may be provided between the first and second pixels PX1 and PX2, and a second FD region 140(2) may be provided between the third and fourth pixels PX3 and PX4. Therefore, the first and second pixels PX1 and PX2 may share the first FD region 140(1), and the first and second pixels PX1 and PX2 and the first FD region 140(1) may form a first sub-share-pixel SPXs1. In some embodiments, the third and fourth pixels PX3 and PX4 share the second FD region 140(2), and the third and fourth pixels PX3 and PX4 and the second FD region 140(2) may form a second sub-share-pixel SPXs2. As a result, the four PDs 110 of the first and second pixels PX1 and PX2 may share one FD region 140(i.e., the first FD region 140(1)), and the four PDs 110 of the third and fourth pixels PX3 and PX4 may share one FD region 140(i.e., the second FD region 140(2)).

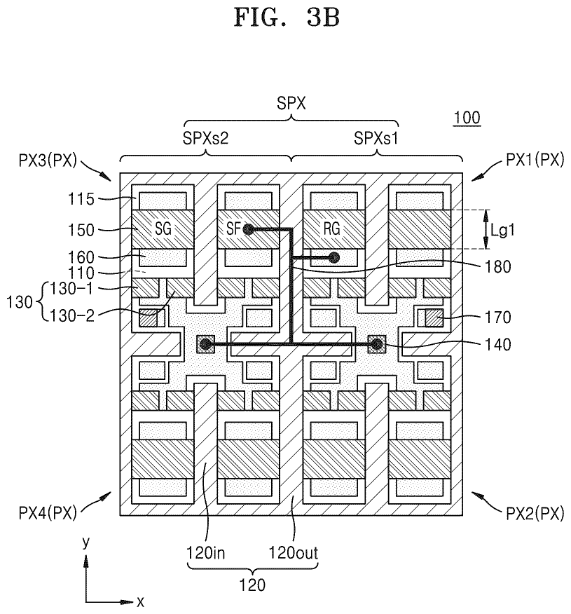

In some embodiments, because two pixels PX form a sub-share-pixel, the share-pixel SPX may include two sub-share-pixels SPXs1 and SPXs2 adjacent to each other in the x-direction. In some embodiments, because two pixels PX share one FD region 140, the share-pixel SPXs may have a simple wiring connection relationship. The wiring connection relationship of the share-pixels SPX is described with reference to FIGS. 3A and 3B.

As illustrated in FIG. 2, the share-pixel SPX may have an approximately square shape in a plan view. However, the planar shape of the share-pixel SPX is not limited to the square shape.

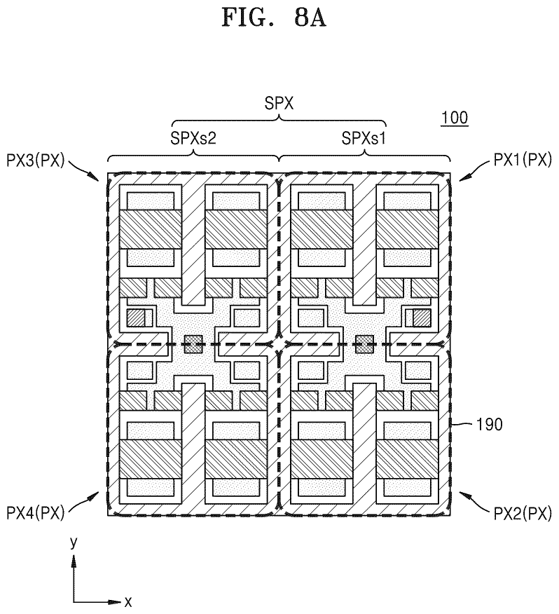

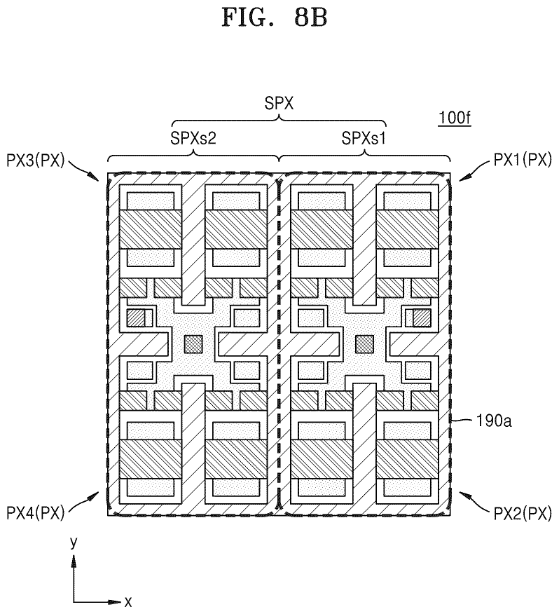

In some embodiments, a micro-lens may be disposed on each of the pixels PX, on each of the sub-share-pixels SPXs1 and SPXs2, or entirely on the share-pixel SPX. The arrangement of the share-pixel SPX and the micro-lens will be described with reference to FIGS. 8A and 8B.

Although only one share-pixel SPX is shown in FIG. 2, the image sensor 100 according to an embodiment may include a plurality of share-pixels SPX arranged in a two-dimensional array structure. That is, in the image sensor 100 according to an embodiment, a plurality of share-pixels SPX may be arranged in the x-direction and the y-direction. The two-dimensional array structure of share-pixels SPX will be described with reference to FIG. 12.

The connection relationship between the PDs 110, the FD regions 140, and the pixel transistors may be described based on the equivalent circuit diagram shown in FIG. 1 as follows: the four PDs PD1-1, PD1-2, PD2-1, and PD2-2 of the first sub-share-pixel SPXs1 may be respectively connected to source regions of corresponding four transfer transistors TX1-1, TX1-2, TX2-1, and TX2-2; and the four PDs PD3-1, PD3-2, PD4-1, and PD4-2 of the second sub-share-pixel SPXs2 may be respectively connected to source regions of corresponding four transfer transistors TX3-1, TX3-2, TX4-1, and TX4-2.

Drain regions of the four transfer transistors TX1-1, TX1-2, TX2-1, and TX2-2 of the first sub-share-pixel SPXs1, and drain regions of the four transfer transistors TX3-1, TX3-2, TX4-1, and TX4-2 of the second sub-share-pixel SPXs2 may be connected to a source region of the reset transistor RX. In other words, a common drain region of the four transfer transistors TX1-1, TX1-2, TX2-1, and TX2-2 of the first sub-share-pixel SPXs1 may correspond to a first FD region FD1 (e.g., the first FD region 140(1) in FIG. 2), and a common drain region of the four transfer transistors TX3-1, TX3-2, TX4-1, and TX4-2 of the second sub-share-pixel SPXs2 may correspond to a second FD region FD2 (e.g., the second FD region 140(2) in FIG. 2). In some embodiments, the source region of the reset transistor RX may correspond to two FD regions 140 connected to each other by wiring. That is, the source region of the reset transistor RX may correspond to the first FD region FD1 of the first sub-share-pixel SPXs1 and the second FD region FD2 of the second sub-share-pixel SPXs2. The first FD region FD1 and the second FD region FD2 may be connected to a source follower gate SF (refer to FIG. 3B) of the source follower transistor SFX through wiring. As seen in FIG. 1, a drain region of the reset transistor RX and a drain region of the source follower transistor SFX may be connected to a power supply voltage Vpix. In some embodiments, a source region of the source follower transistor SFX and a drain region of the selection transistor SX may be connected to each other. In some embodiments, an output line is connected to a source region of the selection transistor SX, and thus, the voltage of the source region of the selection transistor SX may be output as an output voltage Vout.

In some embodiments, the pixel transistors such as the source follower transistor SFX, the reset transistor RX, and the selection transistor SX may be implemented through the gates 150 and the active regions 160 arranged in the pixels PX of the share-pixel SPX. A specific arrangement structure of the source follower transistor SFX, the reset transistor RX, and the selection transistor SX will be described with reference to FIG. 3B.

In some embodiments, the sizes of the pixel transistors may be determined by the sizes of the gates 150. The sizes of the gates 150 in the x-direction may be the widths of the gates 150, and the sizes of the gates 150 in the y-direction may be the lengths of the gates 150. As seen in FIG. 2, the widths of the gates 150 may be determined to some extent by the DTI structure 120. In the image sensor 100 according to an embodiment, the gates 150 may have a first gate length Lg1. In some embodiments, the first gate length Lg1 of the gates 150 may be changed, and thus, the sizes of the pixel transistors may be changed. In the image sensor 100 according to an embodiment, the sizes of the pixel transistors may be changed to improve a charge transfer efficiency, a conversion gain (CG), or the like.

Ground contacts 170 may respectively be disposed in the active regions 160 of the first and second sub-share-pixels SPXs1 and SPXs2. For example, the ground contact 170 of the first sub-share-pixel SPXs1 may be disposed in a right outer portion in the x-direction and in a center portion in the y-direction based on the entirety of the share-pixel SPX, as illustrated in FIG. 2. FIG. 2 illustrates that the ground contact 170 of the first sub-share-pixel SPXs1 is disposed in the first pixel PX1. However, embodiments are not limited thereto and, in some embodiments, the ground contact 170 of the first sub-share-pixel SPXs1 may be disposed in the second pixel PX2. Similarly, the ground contact 170 of the second sub-share-pixel SPXs2 may be disposed in a left outer portion in the x-direction and in a center portion in the y-direction based on the entirety of the share-pixel SPX. In some embodiments, the ground contact 170 of the second sub-share-pixel SPXs2 may be disposed in the fourth pixel PX4.

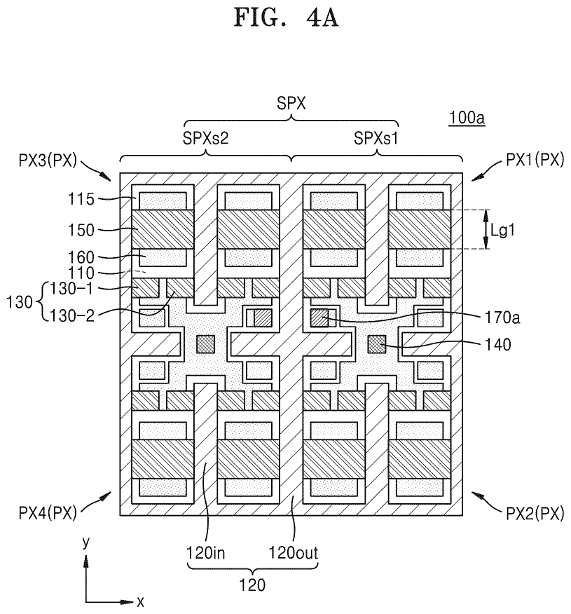

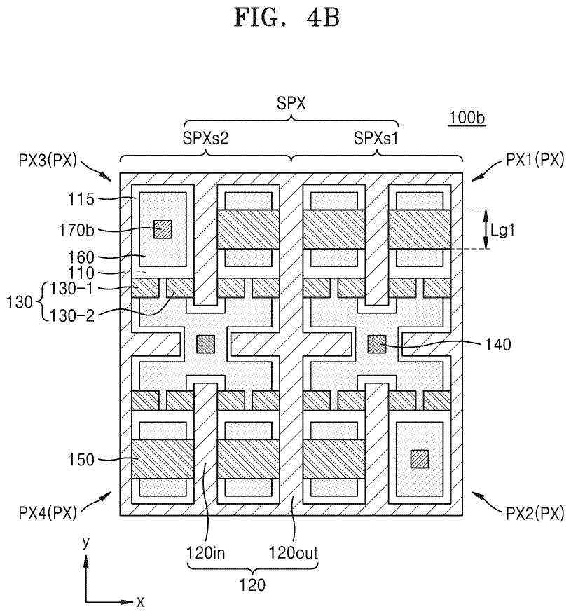

The positions of the ground contacts 170 are not limited to the positions in the share-pixel SPX of the image sensor 100 that are shown in FIG. 2. That is, the ground contacts 170 may be disposed at various positions in the share-pixel SPX according to the structure of the share-pixel SPX. Various arrangement structures of ground contacts will be described with reference to FIGS. 4A, 4B, 6A, 7, and the like.

FIGS. 3A and 3B are plan views respectively illustrating a wiring routing of FD regions of an image sensor Com. of a comparative example and a wiring routing of the FD regions 140 of the image sensor 100 according to an embodiment described with reference to FIG. 1. The following descriptions of FIGS. 3A and 3B are given by referring to FIG. 1 together, and the same descriptions as those given above with reference to FIGS. 1 and 2 are briefly described or omitted for conciseness.

Referring to FIG. 3A, in the image sensor Com. of the comparative example, a share-pixel may include four pixels. In some embodiments, each of the pixels may include two PDs, and one FD region may be disposed in each of the PDs. A ground contact GND may be provided in a center portion of each of the pixels. Therefore, in the image sensor Com. of the comparative example, eight FD regions may be arranged in the share-pixel, and the eight FD regions may be connected to a source region of a reset transistor and a source follower gate of a source follower transistor SF through wiring. As a result, in the image sensor Com. of the comparative example, a wiring routing between the FD regions and pixel transistors may be complex. In general, wiring includes a metal such as copper (Cu), and a complex wiring routing may increase resistance and reduce a conversion gain (CG). Here, the CG may refer to a rate at which charges generated by the PDs are transferred to and accumulated in the FD regions, and the charges may be converted into voltages through the source follower transistor. Furthermore, in the image sensor Com. of the comparative example, the complex wiring routine may make it difficult to increase the arrangement efficiency and the size of pixel transistors and may increase wiring layers.

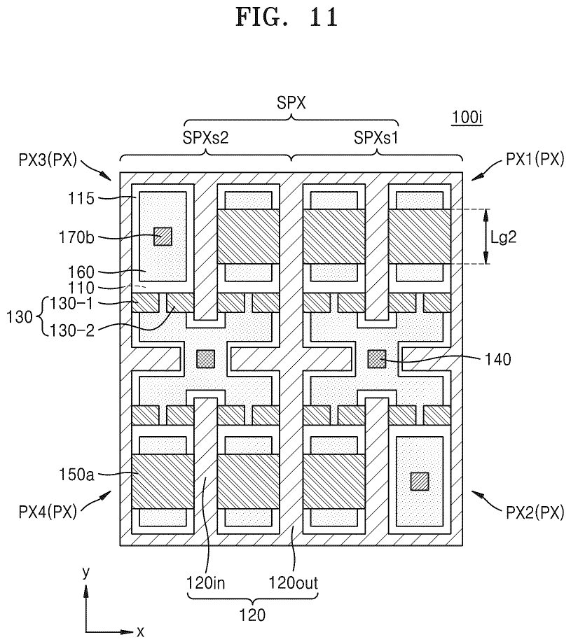

By contrast, referring to FIG. 3B, in the image sensor 100 according to an embodiment, the share-pixel SPX includes four pixels PX, and two pixels PX form one sub-share-pixel while sharing one FD region 140 with each other. Therefore, only two FD regions 140 are disposed in the share-pixel SPX, and the two FD regions 140 are connected to the source region of the reset transistor RX and the source follower gate SF of the source follower transistor SFX through wiring. As a result, as shown in FIG. 3B, in the image sensor 100, the wiring routing between the FD regions 140 and the pixel transistors may be simple. The simple wiring routing may improve a CG by reducing resistance. Furthermore, in the image sensor 100, the simple wiring routing may increase the arrangement efficiency and the size of the pixel transistors and contribute to reducing wiring layers. The increase of the arrangement efficiency and the size of the pixel transistors is further described with reference to FIG. 4B or FIG. 11.

In the image sensor 100, one gate 150 may be disposed per PD 110 in an outer portion of the share-pixel SPX. Therefore, eight gates 150 may be arranged in the share-pixel SPX. At least three of the eight gates 150 may be used for pixel transistors of the share-pixel SPX. For example, in some embodiments, a left gate 150 of the first pixel PX1 may be used as a reset gate RG of the reset transistor RX. In some embodiments, a right gate 150 of the third pixel PX3 may be used as the source follower gate SF of the source follower transistor SFX, and a left gate 150 of the third pixel PX3 may be used as a selection gate SG of the selection transistor SX. The positions of gates 150 used for pixel transistors are not limited thereto. For example, in some embodiments, the reset gate RG may be disposed in the third pixel PX3, and the source follower gate SF and the selection gate SG may be disposed in the first pixel PX1. In some embodiments, the gates 150 of the second pixel PX2 and the fourth pixel PX4 may be used as gates of pixel transistors.

In some embodiments, gates 150 that do not form pixel transistors may correspond to dummy gates. The dummy gates may be used in the image sensor 100 to implement other operating characteristics. For example, the dummy gates may be used to implement a dual CG or a triple CG of the share-pixel SPX. In some embodiments, a dummy gate may be used as an additional source follower gate SF to form a plurality of source follower gates SF.

FIGS. 4A and 4B are plan views respectively illustrating share-pixels SPX of image sensors 100a and 100b according to some embodiments. The following descriptions of FIGS. 4A and 4B are given by referring to FIG. 1 together, and the same descriptions as those given above with reference to FIGS. 1 to 3B are briefly described or omitted for conciseness.

Referring to FIG. 4A, the image sensor 100a may be different from the image sensor 100 described with reference to FIG. 2 in the positions of ground contacts 170a. For example, in the image sensor 100a, the ground contacts 170a may be disposed adjacent to a center portion of the share-pixel SPX in x- and y-directions. For example, the ground contacts 170a may be disposed adjacent to the center portion of the share-pixel SPX in which an outer DTI structure 120out is disposed in a cross shape. In FIG. 4A, the ground contacts 170a are disposed in a first pixel PX1 and a third pixel PX3 in the center portion of the share-pixel SPX. However, the positions of the ground contacts 170a are not limited thereto. For example, according to some embodiments, the ground contacts 170a may be disposed at the center portion of the share-pixel SPX in a second pixel PX2 and a fourth pixel PX4, the first pixel PX1 and the fourth pixel PX4, or the second pixel PX2 and the third pixel PX3.

In the image sensor 100a, a wiring connection structure between FD regions 140 and pixel transistors may be substantially the same as the wiring connection structure shown in FIG. 3B. Hereinafter, when the share-pixel SPX has a structure including two sub-share-pixels SPXs1 and SPXs2 and two FD regions 140, the wiring connection structure between the FD regions 140 and the pixel transistors may be substantially the same as the wiring connection structure shown in FIG. 3B, unless otherwise noted.

Referring to FIG. 4B, the image sensor 100b may be different from the image sensor 100 shown in FIG. 2 in the positions of ground contacts 170b and the arrangement of gates 150. For example, in the image sensor 100b, the ground contacts 170b may be disposed adjacent to an outer portion of the share-pixel SPX in x- and y-directions. For example, assuming that four pixels PX form quadrants, the ground contacts 170b may be disposed in outer portions of second and fourth quadrants. However, the positions of the ground contacts 170b are not limited thereto. For example, in some embodiments, the ground contacts 170b may be disposed in outer portions of first and third quadrants, the outer portions of the first and second quadrants, or outer portions of the third and fourth quadrants.

Because the ground contacts 170b are disposed in the outer portion of the share-pixel SPX in the image sensor 100b, gates to be provided on upper portions of corresponding active regions 160 may be omitted. In some embodiments, although not shown in FIG. 4B, in the image sensor 100b, a right gate 150 of a third pixel PX3 may be a reset gate RG of a reset transistor RX, a right gate 150 of a first pixel PX1 may be a selection gate SG of a selection transistor SX, and a left gate 150 of the first pixel PX1 may be a source follower gate SF of a source follower transistor SFX. In some embodiments, gates of pixel transistors may be disposed in a second pixel PX2 and a fourth pixel PX4. In the image sensor 100b, the positions of the ground contacts 170b may be diversified, and the arrangement efficiency of pixel transistors may be increased.

FIGS. 5A to 5C are a plan view and cross-sectional views respectively illustrating share-pixels SPX and transfer gates 130a and 130a′ of image sensors 100c and 100c′ according to some embodiments. FIGS. 5B and 5C are cross-sectional views respectively illustrating the transfer gate 130a and 130a′ in an x-direction. The following descriptions of FIGS. 5A to 5C are given by referring to FIG. 1 together, and the same descriptions as those given above with reference to FIGS. 1 to 4B are briefly described or omitted for conciseness.

Referring to FIGS. 5A and 5B, the image sensor 100c may be different from the image sensor 100 described with reference to FIG. 2 in that one transfer gate 130a is disposed per PD 110. For example, the image sensor 100c may include a substrate 101, PDs 110, a DTI structure 120, transfer gates 130a, FD regions 140, and gates 150.

The substrate 101 may include a front side FS and a back side BS that is opposite the front side FS (see FIG. 5B). A wiring layer may be disposed on the front side FS of the substrate 101, and a light transmission layer may be disposed on the back side BS of the substrate 101. The light transmission layer may include, for example, a color filter and a micro-lens. Light may be incident on the PDs 110 through the light transmission layer disposed on the back side BS of the substrate 101.

The substrate 101 may be a substrate in which an epitaxial layer of a first conductivity type is grown on a bulk silicon substrate of the first conductivity type (for example, p-type). In some embodiments, the substrate 101 may include only the epitaxial layer in a state in which the bulk silicon substrate is entirely removed. In some embodiments, the substrate 101 may be a bulk silicon substrate including wells of the first conductivity type. In some embodiments, the substrate 101 may include various types of substrates, such as a substrate including an epitaxial layer of a second conductivity type (for example, n-type) or a silicon-on-insulator (SOI) substrate.

The PDs 110 may generate and accumulate charges in proportion to the intensity of light, that is, the amount of light, incident on the PDs 110 through the back side BS of the substrate 101. The PDs 110 may each include, for example, a first dopant region doped with a dopant of the first conductivity type (for example, p-type) and a second dopant region doped with a dopant of the second conductivity type (for example, n-type). The first dopant region and the second dopant region may form a p-n junction. In some embodiments, the substrate 101 may serve as the first dopant region. In this case, the substrate 101 and the second dopant regions may form the PDs 110, and the first dopant regions may not be additionally formed. In some embodiments, the PDs 110 may be disposed in the substrate 101 respectively at centers of pixels PX. For example, as shown in FIG. 5B, a PD 110 may be disposed in the substrate 101 below a transfer gate 130a of a transfer transistor TX.

In the image sensor 100c, one transfer transistor TX is disposed per PD 110, and the transfer transistor TX may include a transfer gate 130a. Considering the functional aspect of transistors, the transfer gate 130a, the PD 110, and an FD region 140 may form each transfer transistor TX. In other words, the PD 110/FD region 140 may form a source/drain of the transfer transistor TX.

The transfer gate 130a may include polysilicon. However, the material of the transfer gate 130a is not limited to polysilicon. For example, in some embodiments, the transfer gate 130a may be formed as a multi-layer structure including a barrier layer and at least one metal layer. In some embodiments, the transfer gate 130a may have, for example, a dual vertical gate structure. Therefore, the transfer gate 130a may include two vertical extension portions 132 and a connection portion 134. The two vertical extension portions 132 may extend in a vertical direction into the inside of the substrate 101 and may be spaced apart from each other in an x-direction. Here, the vertical direction may refer to a z-direction perpendicular to an upper surface of the substrate 101. The connection portion 134 may connect the two vertical extension portions 132 to each other on the upper surface of the substrate 101. Here, the vertical extension portions 132 and the connection portion 134 are only terms for distinguishing therebetween, and the vertical extension portions 132 and the connection portion 134 may include the same material and may be formed in one piece. For example, in some embodiments, the vertical extension portions 132 and the connection portion 134 may be formed in one piece using polysilicon.

As shown in FIG. 5A, the horizontal cross-section of the transfer gate 130a may have a rectangular shape. At a level above the connection portion 134 in the z-direction, the horizontal cross-section of the transfer gate 130a may have a rectangular shape. At a level below the connection portion 134 in the z-direction, the horizontal cross-section of the transfer gate 130a may have a shape in which two small rectangular shapes of the vertical extension portions 132 are apart from each other in the x-direction.

Lower and lateral surfaces of the vertical extension portions 132 and a lower surface of the connection portion 134 may be surrounded by a gate insulating layer 135. For example, the gate insulating layer 135 may be provided between the vertical extension portions 132 and the substrate 101, between the connection portion 134 and the substrate 101, and on the upper surface of the substrate 101 outside the transfer gate 130a in the x-direction.

In the image sensor 100c, the transfer gate 130a having a dual vertical gate structure is provided, and thus, leakage of charge may be reduced as in the case in which two transfer gates 130 having a vertical gate structure are provided. In some embodiments, because the connection portion 134 provided in an upper portion of the transfer gate 130a is wide, a gate contact 180 may not have a large area and may not be misaligned. That is, because the connection portion 134 provided in an upper portion of the transfer gate 130a is wide, the gate contact 180 may have a relatively small area and it may be easy to align the gate contact on the connection portion 134. For example, when only two transfer gates are provided without a connection portion, a contact area may increase because gate contacts are disposed respectively on the transfer gates. In some embodiments, because upper surfaces of the two transfer gates are narrow, misalignment may occur between the gate contacts and the two transfer gates. However, in the image sensor 100c, the transfer gate 130a includes the connection portion 134. Thus, only one gate contact 180 may be used, and the area of the gate contact 180 may be reduced. Moreover, because the connection portion 134 has a relatively large upper surface area, misalignment between the connection portion 134 and the gate contact 180 may be reduced.

In some embodiments, a spacer having a certain thickness may be disposed between the connection portion 134 of the transfer gate 130a and the substrate 101 to remove a potential hump of the transfer gate 130a. The potential hump may refer to a phenomenon in which a field concentrates at an edge of an active region corresponding to a bending portion of a gate. Owing to the spacer, the length of the vertical extension portions 132 of the transfer gate 130a may increase by the thickness of the spacer. Therefore, the thickness of the spacer may be appropriately determined by considering the length of the vertical extension portions 132 of the transfer gate 130a and the effect of removing the potential hump.

Referring to FIGS. 5A and 5C, the image sensor 100c′ may be similar to the image sensor 100c described with reference to FIG. 5B in that one transfer gate 130a′ is disposed per PD 110. However, the image sensor 100c′ may be different from the image sensor 100c described with reference to FIG. 5B in that the transfer gate 130a′ may have a single vertical gate structure. For example, in some embodiments, the image sensor 100c′ may include a substrate 101, a PD 110, a DTI structure 120, a transfer gate 130a′, an FD region 140, and a gate 150. The substrate 101, the PD 110, the DTI structure 120, the FD region 140, and the gate 150 may be the same as those of the image sensors 100 and 100c described with reference to FIGS. 2 and 5B and thus repeated description thereof is omitted for conciseness.

The transfer gate 130a′ may have a single vertical gate structure as shown in FIG. 5C. Therefore, the transfer gate 130a′ may include a vertical extension portion 132 and a horizontal extension portion 136. The vertical extension portion 132 may extend in a vertical direction into the inside of the substrate 101. The horizontal extension portion 136 may extend on an upper surface of the substrate 101 in a horizontal direction from the vertical extension portion 132. The vertical extension portion 132 and the horizontal extension portion 136 of the transfer gate 130a′ are only terms for distinguishing therebetween, and the vertical extension portion 132 and the horizontal extension portion 136 may include the same material and may be formed in one piece.

In the image sensor 100c′, the vertical extension portion 132 of the transfer gate 130a′ may extend vertically into the inside of the substrate 101, and the horizontal extension portion 136 may extend on the substrate 101. Therefore, even when the vertical extension portion 132 is small, a sufficient area of a gate contact 180 may be secured through the horizontal extension portion 136. As a result, the gate contact 180 may not have a large area and may not be misaligned. In other words, the gate contact 180 may have a relatively small area and may be more easily aligned on the horizontal extension portion 136. In some embodiments, a spacer having a certain thickness may be disposed between the horizontal extension portion 136 of the transfer gate 130a and the substrate 101 to remove a potential hump of the transfer gate 130a′,

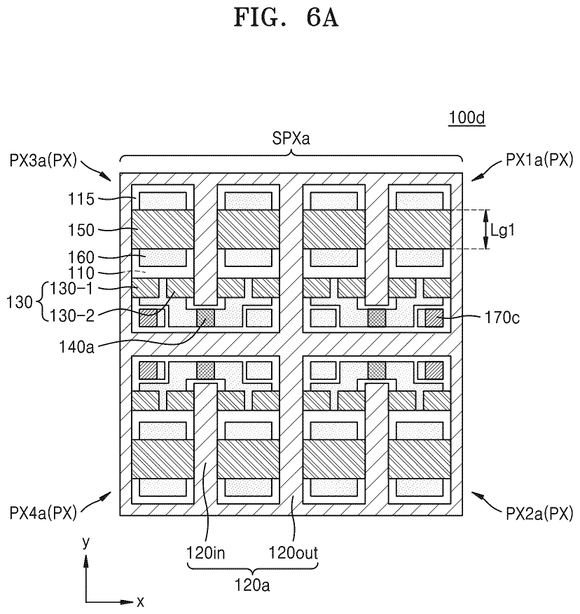

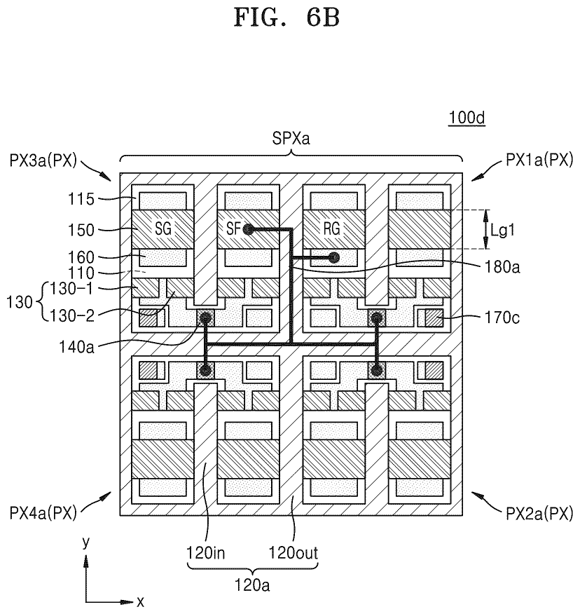

FIGS. 6A and 6B are plan views respectively illustrating a share-pixel SPXa of an image sensor 100d according to an embodiment and a plan view illustrating a wiring routing of FD regions of the image sensor 100d according to an embodiment. The following descriptions of FIGS. 6A and 6B are given by referring to FIG. 1 together, and the same descriptions as those given above with reference to FIGS. 1 to 5C are briefly described or omitted for conciseness.

Referring to FIGS. 6A and 6B, the image sensor 100d may be different from the image sensor 100 described with reference to FIG. 2 in that two pixels PX do not share an FD region 140a. For example, in the image sensor 100d, the share-pixel SPXa may include four pixels PX1a to PX4a, and the concept of configuring a sub-share-pixel by two pixels PX may not be used. In some embodiments, the four pixels PX1a to PX4a may be completely separated from each other by a DTI structure 120a, for example, by an outer DTI structure 120out.

Each of the pixels PX may include an FD region 140a. Therefore, in each of the pixels PX, two PDs 110 may share the FD region 140a. As shown in FIG. 6B, according to an arrangement structure of the FD regions 140a, four FD regions 140a of the share-pixel SPXa may be connected through wiring to a source region of a reset transistor RX and a source follower gate SF of a source follower transistor SFX.

In some embodiments, a ground contact 170c may be disposed in each of the pixels PX. For example, the ground contact 170c may be disposed in each of the pixels PX1s in a portion of the share-pixel SPXa that is an outer portion in an x-direction and adjacent to a center portion in a y-direction. However, the position of the ground contact 170c is not limited thereto. For example, in some embodiments, the ground contact 170c may be disposed in each of the pixels PX adjacent to a center portion of the share-pixel SPXa in the x and y-directions.

In some embodiments, a wiring connection structure between the FD regions 140a and pixel transistors of the image sensor 100d may be simpler than the wiring connection structure of the FD regions of the image sensor Com. of the comparative example shown in FIG. 3A. Therefore, the image sensor 100d may also contribute to improving a CG, increasing the arrangement efficiency and the size of pixel transistors, and reducing wiring layers.

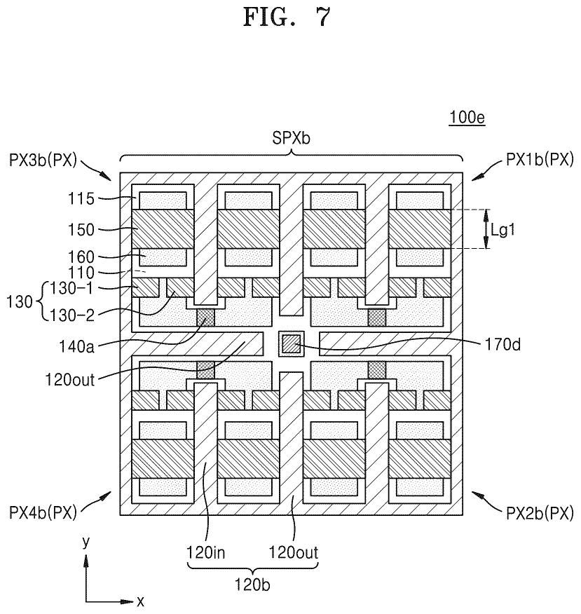

FIGS. 7 to 11 are plan views respectively illustrating share-pixels SPXb and SPX of image sensors 100e, 100, 100f, 100g, 100h, and 100i according to some embodiments. The following descriptions of FIGS. 7 to 11 are given by referring to FIG. 1 together, and the same descriptions as those given above with reference to FIGS. 1 to 6B are briefly described or omitted for conciseness.

Referring to FIG. 7, the image sensor 100e may be different from the image sensor 100 described with reference to FIG. 2 in the structure of the share-pixel SPXb. For example, in the image sensor 100e, the share-pixel SPXb may include four pixels PX1b to PX4b, and the concept of configuring a sub-share-pixel by two pixels PX may not be used. Therefore, each of the pixels PX may include an FD region 140a. Therefore, in each of the pixels PX, two PDs 110 may share the FD region 140a.

The layout and wiring connection structure of the FD regions 140a may be substantially the same as the layout and wiring connection structure of the FD regions 140a shown in FIG. 6B. Hereinafter, when each pixel PX of a share-pixel includes an FD region 140a, the wiring connection structure between FD regions 140a and pixel transistors may be substantially the same as the wiring connection structure shown in FIG. 6B,unless otherwise noted.

In the image sensor 100e, the four pixels PX1b to PX4b of the share-pixel SPXb may be incompletely separated from each other by a DTI structure 120b, for example, an outer DTI structure 120out. For example, a ground contact 170d that is a common ground contact of the share-pixel SPXb may be disposed in a center portion of the share-pixel SPXb in x and y-directions. Due to the ground contact 170d disposed in the center portion of the share-pixel SPXb, a portion of the outer DTI structure 120out extending in the x-direction may be divided such that a portion of the outer DTI structure 120out is disposed on either side of the ground contact 170d in the x-direction, and a portion of the outer DTI structure 120out extending in the y-direction may be divided such that a portion of the outer DTI structure 120out is disposed on either side of the ground contact 170 in the y-direction.

Referring to FIG. 8A, in the image sensor 100, four micro-lenses 190 may be disposed corresponding to four pixels PX of the share-pixel SPX. As described above, the micro-lenses 190 may be disposed on a lower surface of a substrate 101. Thus, FIG. 8A illustrates dashed lines corresponding to the micro-lenses 190. In some embodiments, although the micro-lenses 190 are illustrated as having a tetragonal planar shape corresponding to the planar shape of the pixels PX, the planar shape of the micro-lenses 190 is not limited to a tetragonal square and may have a circular or elliptical shape.

In some embodiments, each of the pixels PX includes two PDs 110, and a transfer transistor TX is disposed corresponding to each of the PDs 110. Thus, at least one of the pixels PX may be used to implement autofocusing (AF). In some embodiments, AF may be performed in various ways. For example, AF may be performed by a method such as a contrast AF method, a phase-difference AF method, an imaging plane phase-difference AF method, or a dual pixel AF method. The dual pixel AF method refers to a method of using two or more PDs 110 as one AF pixel. According to the dual pixel AF method, the PDs 110 of the AF pixel are individually controlled such that when AF information is used, the PDs 110 may be operated like a phase-difference sensor using photodetection signals of the PDs 110, and when image information is used, photodetection signals of the PDs 110 may be combined together and output as one image signal. The image sensor 100 may perform AF by the dual pixel AF method using two PDs 110 in a pixel PX.

Referring to FIG. 8B, in the image sensor 100f, two micro-lenses 190a corresponding to two sub-share-pixels SPXs1 and SPXs2 of the share-pixel SPX may be provided. The micro-lenses 190a may be disposed on a lower surface of a substrate 101, and FIG. 8B illustrates dashed lines corresponding to the micro-lenses 190a. In some embodiments, the micro-lenses 190a may have a tetragonal planar shape extending in a y-direction and corresponding to the planar shape of the sub-share-pixels SPXs1 and SPXs2. However, the micro-lenses 190 are not limited thereto and may have an elliptical planar shape extending in the y-direction.

In the image sensor 100f, each of the sub-share-pixels SPXs1 and SPXs2 may include two pixels PX. Therefore, upper and lower pixels PX of each of the sub-share-pixels SPXs1 and SPXs2 may be used to implement AF. That is, in the image sensor 100f, at least one of the sub-share-pixels SPXs1 and SPXs2 may perform AF by the dual pixel AF method using two pixels PX.

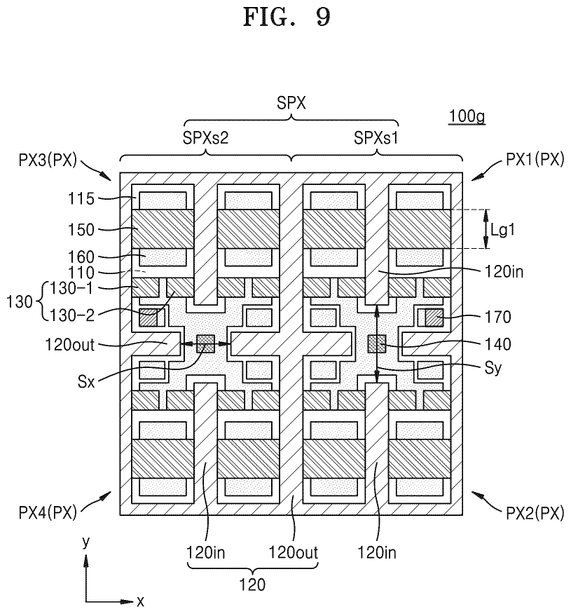

Referring to FIG. 9, the structure of the share-pixel SPX of the image sensor 100g may be substantially the same as the structure of the share-pixel SPX of the image sensor 100 described with reference to FIG. 2. For example, the share-pixel SPX may include two sub-share-pixels SPXs1 and SPXs2 adjacent to each other in an x-direction, and each of the sub-share-pixels SPXs1 and SPXs2 may include two pixels PX adjacent to each other in a y-direction.

In the image sensor 100g, an FD region 140 may be disposed in a center portion of each of the sub-share-pixels SPXs1 and SPXs2 and may be shared by two pixels PX. In some embodiments, the FD region 140 may be formed in an active region 160 disposed in the center portion of each of the sub-share-pixels SPXs1 and SPXs2.

Because the FD region 140 is disposed in the center portion of each of the sub-share-pixels SPXs1 and SPXs2, an outer DTI structure 120out extending in the x-direction within each of the sub-share-pixels SPXs1 and SPXs2 may be divided into two parts on both sides in the x-direction by the active region 160 including the FD region 140. The two parts of the outer DTI structure 120out may be spaced apart from each other in the x-direction by, for example, a first separation distance Sx.

In some embodiments, because the FD region 140 is disposed in the center portion of each of the sub-share-pixels SPXs1 and SPXs2, inner DTI structures 120 in provided in the two pixels PX adjacent to each other in the y-direction may be separated from each other by the active region 160 including the FD region 140. The inner DTI structures 120 in provided in the two pixels PX adjacent to each other in the y-direction may be apart from each other in the y-direction by, for example, a second separation distance Sy.

In the image sensor 100g, at least one of the first separation distance Sx and the second separation distance Sy may be adjusted to adjust a potential barrier between adjacent pixels PX and/or prevent optical crosstalk. For example, the first separation distance Sx may be reduced to increase a potential barrier between pixels PX adjacent to each other in the y-direction in each of the sub-share-pixels SPXs1 and SPXs2, thereby enhancing electrical isolation and reducing optical crosstalk. In some embodiments, the second separation distance Sy may be reduced to enhance electrical isolation between PDs 110 adjacent to each other in the x-direction in each of the pixels PX, thereby reducing optical crosstalk. In some embodiments, adjustment of the first separation distance Sx may correspond to adjustment between pixels (inter-pixel adjustment), and adjustment of the second separation distance (Sy) may correspond to adjustment in pixels (in-pixel adjustment).

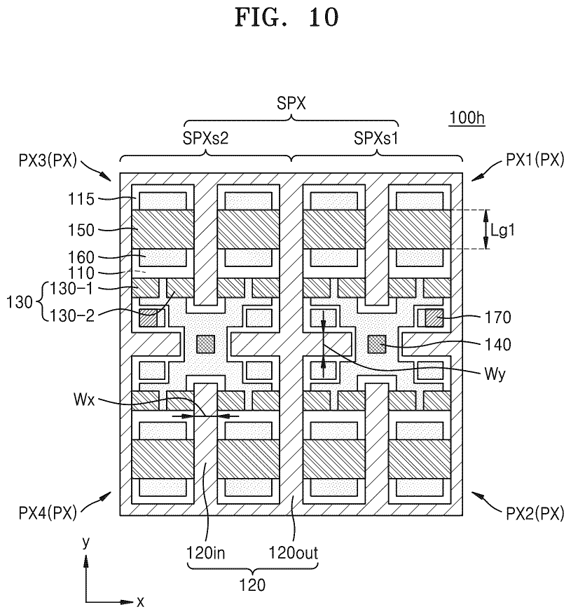

Referring to FIG. 10, the structure of the share-pixel SPX of the image sensor 100h may be substantially the same as the structure of the share-pixel SPX of the image sensor 100 described with reference to FIG. 2. For example, the share-pixel SPX may include two sub-share-pixels SPXs1 and SPXs2 adjacent to each other in an x-direction, and each of the sub-share-pixels SPXs1 and SPXs2 may include two pixels PX adjacent to each other in a y-direction.

In the image sensor 100h, an inner DTI structure 120 in of a DTI structure 120 may have a first width Wx in the x-direction. In some embodiments, an outer DTI structure 120out of the DTI structure 120 may have a predetermined width in the x-direction or y-direction. For example, outer DTI structures 120out arranged in center portions of the sub-share-pixels SPXs1 and SPXs2 in the y-direction and extending in the x-direction may have a second width Wy in the y-direction.

In the image sensor 100h, at least one of the first width Wx and the second width Wy may be adjusted to adjust a potential barrier between adjacent pixels PX and/or prevent optical crosstalk. For example, the first width Wx may be increased to enhance electrical isolation between PDs 110 in the x-direction and decrease optical crosstalk. In some embodiments, the second width Wy may be increased to enhance electrical isolation between adjacent pixels PX in the y-direction and reduce optical crosstalk in each of the sub-share-pixels SPXs1 and SPXs2. In some embodiments, adjustment of the first width Wx may correspond to adjustment in pixels PX, and adjustment of the second width Wy may correspond to adjustment between pixels PX.

Referring to FIG. 11, the structure of the share-pixel SPX of the image sensor 100i may be similar to the structure of the share-pixel SPX of the image sensor 100b described with reference to FIG. 4B. For example, ground contacts 170b may be disposed in an outer portion of the share-pixel SPX in x- and y-directions. In some embodiments, gates may not be disposed in active regions 160 in which the ground contacts 170b are disposed.

In the image sensor 100i, the size of gates 150a of the share-pixel SPX may be greater than the size of the gates 150 of the share-pixel SPX of the image sensor 100b described with reference to FIG. 4B. For example, in the image sensor 100i, the gates 150a may have a second gate length Lg2 in the y-direction. The second gate length Lg2 may be greater than the first gate length Lg1. Therefore, the size of pixel transistors, such as a reset transistor RX, a source follower transistor SFX, and a selection transistor SX, may be increased by increasing the size of the gates 150a.

In the image sensor 100i, the gates 150a may have the second gate length Lg2. In some embodiments, the second gate length Lg2 of the gates 150a may be changed, and thus, the size of the pixel transistors may be changed. For example, in the image sensor 100i, characteristics such as charge transfer efficiency and a CG may be improved by increasing the size of the gates 150a and the size of the pixel transistors.

FIG. 12 is a plan view illustrating a two-dimensional array structure in which the share-pixels SPX of the image sensor 100 described with reference to FIG. 2 are two-dimensionally arranged. The following description of FIG. 12 is given by referring to FIGS. 1 and 2 together, and the same descriptions as those given above with reference to FIGS. 1 to 11 are briefly described or omitted for conciseness.

Referring to FIG. 12, the image sensor 100 may have a two-dimensional array structure in which the share-pixels SPX described with reference to FIG. 2 are arranged in the x- and y-directions. The share-pixels SPX adjacent to each other in the x-direction and y-direction may be spaced apart from each other by the DTI structure 120, for example, the outer DTI structures 120out. FIG. 12 illustrates that the share-pixels SPX of the image sensor 100 described with reference to FIG. 2 are arranged in a two-dimensional array structure. In various embodiments, the share-pixels SPX, SPXa, and SPXb of the image sensors 100a to 100i described with reference to FIGS. 3B to 5A and FIGS. 6A to 11 may also be arranged in a two-dimensional array structure.

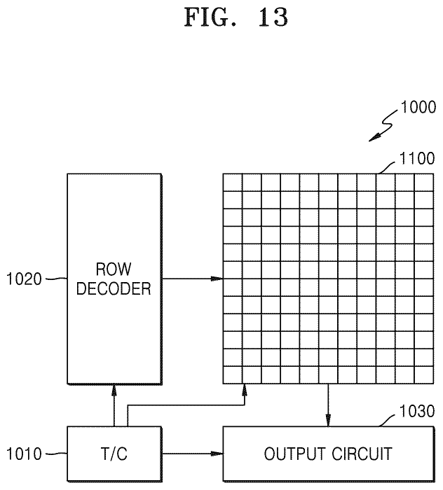

FIG. 13 is a block diagram entirely illustrating an image sensor 1000 according to an embodiment. The following description of FIG. 13 is given by referring to FIGS. 1 and 2 together, and the same descriptions as those given above with reference to FIGS. 1 to 12 are briefly described or omitted for conciseness.

Referring to FIG. 13, the image sensor 1000 may include a pixel array 1100, a timing controller (T/C) 1010, a row decoder 1020, and an output circuit 1030. The image sensor 1000 may be, for example, a charge coupled device (CCD) image sensor or a complementary metal oxide semiconductor (CMOS) image sensor.

In some embodiments, the image sensor 1000 may be any one of the image sensors 100 and 100a to 100i described with reference to FIGS. 2, 3B to 5A, and 6A to 11. Therefore, the pixel array 1100 may include a plurality of share-pixels SPX, SPXa, or SPXb that are arranged in a plurality of rows and a plurality of columns to form a two-dimensional array structure. The row decoder 1020 may select one row from the rows of the pixel array 1100 in response to a row address signal that is output from the timing controller 1010. The output circuit 1030 may output image signals in units of columns from a plurality of pixels and/or share-pixels SPX arranged in the selected row. The output circuit 1030 may include an analog-to-digital converter (ADC). For example, the output circuit 1030 may include a plurality of ADCs arranged respectively for the columns between a column decoder and the pixel array 1100, or one ADC disposed at an output terminal of the column decoder. In some embodiments, the timing controller 1010, the row decoder 1020, and the output circuit 1030 may be implemented as one chip or separate chips.

In the image sensor 1000, each of the share-pixels SPX may include two sub-share-pixels SPXs1 and SPXs2, and each of the sub-share-pixels SPXs1 and SPXs2 may include two pixels PX and one FD region 140. Therefore, a wiring connection relationship between the FD regions 140 and pixel transistors may be simple, thereby improving a CG, increasing the arrangement efficiency and the size of the pixel transistors, and reducing wiring layers.

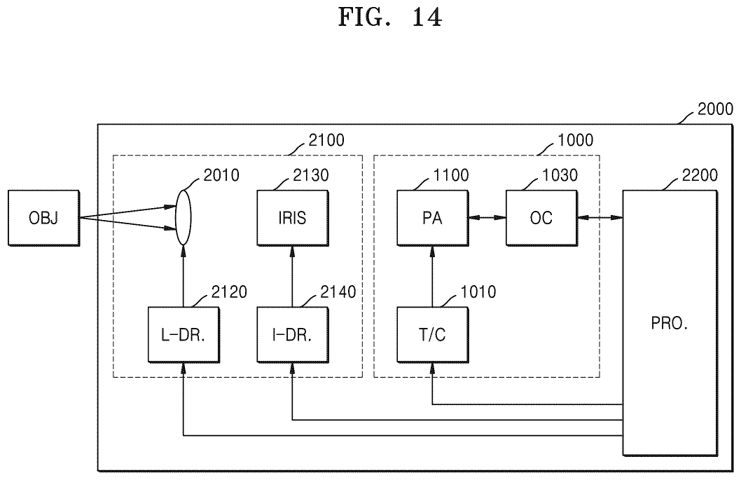

FIG. 14 is a block diagram illustrating an electronic device 2000 including an image sensor 1000 according to an embodiment. The following descriptions of FIG. 14 is given by referring to FIGS. 1, 2, and 13 together, and the same descriptions as those given above with reference to FIGS. 1 to 13 are briefly described or omitted for conciseness.

Referring to FIG. 14, the electronic device 2000 including the image sensor 1000 (hereinafter simply referred to as the “electronic device 2000”) may include an imaging device 2100, the image sensor 1000, and a processor 2200. The electronic device 2000 may be, for example, a camera. The imaging device 2100 may form an optical image by focusing light reflected from an object OBJ. The imaging device 2100 may include an objective lens 2010, a lens driver (L-DR.) 2120, an iris 2130, and an iris driver (I-DR.) 2140. Although FIG. 14 illustrates only one lens for ease of illustration, in some embodiments, the objective lens 2010 may include a plurality of lenses having different sizes and shapes. In some embodiments, the electronic device 2000 may be a mobile camera, and in the mobile camera, the iris 2130 and the iris driver 2140 may be omitted.

The lens driver (L-DR.) 2120 may communicate information about focus detection with the processor 2200 and may adjust the position of the objective lens 2010 according to a control signal received from the processor 2200. The lens driver 2120 may move the objective lens 2010 to adjust the distance between the objective lens 2010 and the object OBJ, or may adjust the positions of individual lenses included in the objective lens 2010. The lens driver 2120 may drive the objective lens 2010 to adjust a focus on the object OBJ. In some embodiments, the lens driver 2120 may receive AF information and adjust the positions of individual lenses of the objective lens 2010 to adjust a focus.

The iris driver (I-DR.) 2140 may communicate information about the amount of light with the processor 2200 and may adjust the iris 2130 according to a control signal received from the processor 2200. For example, the iris driver 2140 may increase or decrease the diameter of the iris 2130 depending on the amount of light entering the interior of the electronic device 2000 through the objective lens 2010. In some embodiments, the iris driver 2140 may adjust the opening time of the iris 2130.

The image sensor 1000 may generate an electrical image signal based on the intensity of incident light. The image sensor 1000 may be, for example, any one of the image sensors 100 and 100a to 100i described with reference to FIGS. 2, 3B to 5A, and 6A to 11. In some embodiments, the image sensor 1000 may be the image sensor 1000 described with reference to FIG. 13. Therefore, the image sensor 1000 may include a pixel array 1100, a timing controller (T/C) 1010, and an output circuit 1030. In some embodiments, although not shown in FIG. 14, the image sensor 1000 may further include a row decoder 1020.

The processor 2200 may control the overall operation of the electronic device 2000 and perform an image processing function. For example, the processor 2200 may provide control signals for the operations of components, such as the lens driver 2120, the iris driver 2140, and the timing controller 1010.

While various embodiments have been particularly shown and described with reference to the drawings, it will be understood that various changes in form and details may be made therein without departing from the spirit and scope of the following claims.

What is claimed is:

1. An image sensor comprising:
a plurality of pixels, each comprising two photodiodes (PDs) arranged side-by-side in a first direction;
a deep trench isolation (DTI) structure comprising an inner DTI structure that extends in a second direction perpendicular to the first direction and that separates the two PDs of each of the plurality of pixels from each other in the first direction, and an outer DTI structure that extends in the first direction and the second direction and that separates the plurality of pixels from each other in the first direction and the second direction;
a floating diffusion (FD) region arranged between a center portion of the outer DTI structure extending in the first direction and an edge of the inner DTI structure; and
a plurality of transfer gates (TGs) disposed adjacent to the FD region such that at least one TG of the plurality of TGs is disposed on each PD,
wherein, for each of the plurality of pixels, the two PDs of the pixel share the FD region.

2. The image sensor of claim 1, wherein each group of two pixels of the plurality of pixels that are adjacent to each other in the second direction forms a sub-share-pixel,
each group of two sub-share-pixels adjacent to each other in the first direction forms a share-pixel, and
the share-pixels are arranged in the first direction and in the second direction in a two-dimensional array structure.

3. The image sensor of claim 2, wherein, in each sub-share-pixel, the FD region is disposed between the two pixels of the sub-share-pixel, and
the two PDs of each of the two pixels of the sub-share-pixel share the FD region of the sub-share-pixel.

4. The image sensor of claim 3, wherein each sub-share-pixel comprises a ground contact region, and
the ground contact regions are arranged in one of:
a first arrangement structure in which the ground contact regions are arranged in a portion of each of the share-pixel that is an outer portion in the first direction and a center portion in the second direction;
a second arrangement structure in which the ground contact regions are arranged adjacent to a center portion of each of the share-pixels in the first direction and in the second direction; and
a third arrangement structure in which the ground contact regions are arranged adjacent to an outer portion of each of the share-pixels in the first direction and the second direction.

5. The image sensor of claim 4, wherein active regions and gates corresponding to the PDs are arranged in outer portions of the pixels in the second direction,
wherein, in the third arrangement structure, the ground contact regions are arranged instead of the gates in the active regions corresponding to a portion of the PDs, and
wherein a length of the gates in the first direction in the third arrangement structure is greater than a length of the gates in the first direction in the first arrangement structure and the second arrangement structure.

6. The image sensor of claim 3, wherein, in each sub-share pixel:
the FD region is arranged in a center portion of the sub-share-pixel,
two inner DTI structures of the sub-share-pixel are separated from each other in the second direction by the FD region, and
the outer DTI structure of the sub-share pixel that extends in the first direction and separates the two pixels of the sub-share pixel is divided into two parts in the first direction with one part on either side of the FD region.

7. The image sensor of claim 6, wherein a separation distance between the two inner DTI structures in the second direction, and a separation distance between the two parts of the outer DTI structure in the first direction vary.

8. The image sensor of claim 2, wherein a width of the inner DTI structure in the first direction, and a width of the outer DTI structure in the first direction or the second direction vary.

9. The image sensor of claim 2, further comprising:
a reset gate (RG) disposed in one of the pixels of each of the share-pixels at an inner portion of the share-pixel; and
a source follower gate (SF) disposed in at least one other of the pixels of each of the share-pixels at a position adjacent to the RG at the inner portion of the share-pixel,
wherein, in each of the sub-share-pixels, two FD regions are disposed corresponding to the two pixels of the sub-share-pixel and the two FD regions are connected to the SF through wiring, or one FD region is disposed and shared by the two pixels of the sub-share-pixel and the one FD region is connected to the SF through wiring.

10. The image sensor of claim 2, wherein, in each of the sub-share-pixels:
two FD regions are disposed corresponding to the two pixels of the sub-share-pixel, and
ground contact regions of the two pixels are disposed in a portion of each of the share-pixels that is an outer portion in the first direction and is adjacent to a center portion in the second direction.

11. The image sensor of claim 2, wherein, in each of the sub-share-pixels:
two FD regions are disposed corresponding to the two pixels of the sub-share-pixel, and
wherein in each of the share-pixels:
a ground contact region is disposed in a center portion in the first direction and the second direction, and
an outer DTI structure extending in the first direction and an outer DTI structure extending in the second direction are each divided by the ground contact region.

12. The image sensor of claim 2, further comprising micro-lenses covering the sub-share-pixels,
wherein the image sensor performs autofocusing.

13. The image sensor of claim 1, wherein two TGs are arranged on each of the PDs.

14. An image sensor comprising:
a share-pixel comprising four pixels, each of the four pixels comprising two photodiodes (PDs) arranged side-by-side in a first direction;
a deep trench isolation (DTI) structure comprising an inner DTI structure that extends in a second direction perpendicular to the first direction and separates the two PDs of each of the four pixels from each other in the first direction, and an outer DTI structure that extends in the first direction and the second direction and separates the four pixels from each other in the first direction and the second direction;
a floating diffusion (FD) region disposed between a center portion of the outer DTI structure extending in the first direction and an edge of the inner DTI structure;
a plurality of transfer gates (TGs) arranged adjacent to the FD region such that at least one TG of the plurality of TGs is disposed on each PD;
a reset gate (RG) disposed in any one of the four pixels of the share-pixel at an inner portion of the share-pixel; and
a source follower gate (SF) disposed in at least one other pixel of the four pixels of the share-pixel and adjacent to the RG at the inner portion of the share-pixel,
wherein the two PDs of each of the pixels share the FD region.

15. The image sensor of claim 14, wherein each group of two pixels that are adjacent to each other in the second direction, of the four pixels, forms a sub-share-pixel,
the share-pixel comprises two sub-share-pixels adjacent to each other in the first direction,
the FD region is disposed between the two pixels of each of the sub-share-pixels, and
the four PDs of each of the sub-share-pixels share the FD region of the sub-share pixel.

16. The image sensor of claim 15, wherein each sub-share-pixel comprises a ground contact region, and
the ground contact regions are arranged in one of:
a first arrangement structure in which the ground contact regions are arranged in a portion of the share-pixel that is an outer portion in the first direction and a center portion in the second direction;
a second arrangement structure in which the ground contact regions are arranged adjacent to a center portion of the share-pixel in the first direction and in the second direction; and
a third arrangement structure in which the ground contact regions are arranged adjacent to an outer portion of the share-pixel in the first direction and the second direction.

17. The image sensor of claim 15, wherein, in each sub-share-pixel:
two FD regions are disposed corresponding to the two pixels of the sub-share-pixel,
a ground contact region of the share-pixel is disposed in a center portion of the share-pixel in the first direction and the second direction, and
in the share-pixel, an outer DTI structure extending in the first direction and an outer DTI structure extending in the second direction are each divided by the ground contact region.

18. The image sensor of claim 14, wherein two FD regions of the share-pixel are connected to the SF through wiring, or four FD regions of the share-pixel are connected to the SF through wiring.

19. An image sensor comprising:
a share-pixel comprising four pixels, each of the four pixels comprising two photodiodes (PDs) arranged side-by-side in a first direction;
a deep trench isolation (DTI) structure comprising an inner DTI structure that extends in a second direction perpendicular to the first direction and separates the two PDs of each of the four pixels from each other in the first direction, and an outer DTI structure that extends in the first direction and the second direction and separates the four pixels from each other in the first direction and the second direction;
a floating diffusion (FD) region disposed between a center portion of the outer DTI structure extending in the first direction and an edge of the inner DTI structure; and
a plurality of transfer gates (TGs) arranged adjacent to the FD region such that at least one TG of the plurality of TGs is disposed on each PD,
wherein each group of two pixels that are adjacent to each other in the second direction, of the four pixels, forms a sub-share-pixel,
the share-pixel comprises two sub-share-pixels adjacent to each other in the first direction,
the FD region is disposed between the two pixels of each of the sub-share-pixels, and
the four PDs of each of the sub-share-pixels share the FD region of the sub-share-pixel.

20. The image sensor of claim 19, wherein each sub-share-pixel comprises a ground contact region, and
the ground contact regions are arranged in one of:
a first arrangement structure in which the ground contact regions are arranged in a portion of the share-pixel that is an outer portion in the first direction and a center portion in the second direction;
a second arrangement structure in which the ground contact regions are arranged adjacent to a center portion of the share-pixel in the first direction and in the second direction; and
a third arrangement structure in which the ground contact regions are arranged adjacent to an outer portion of the share-pixel in the first direction and in the second direction,
wherein two FD regions of the share-pixel are connected to a source follower gate (SF) through wiring.
